(19) United States
(12) Patent Application Publication
(10) Pub. No.: US 2006/0267106 A1
(43) Pub. Date: Nov. 30, 2006

(54) Novel semiconductor device with improved channel strain effect

(75) Inventors: Donald Y. Chao, Shin-Chu (TW); Chien-Hao Chen, Ilan County (TW); Ling-Yen Yeh, Hsinchu City (TW); Tze-Liang Lee, Hsinchu (TW); Shih-Chang Chen, Hsin-Chu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Taiwan Semiconductor Manufacturing Company, Ltd.

(21) Appl. No.: 11/137,495

(22) Filed: May 26, 2005

(51) Int. Cl. H01L 29/772

(52) U.S. Cl. 257/382; 257/383; 257/384

(57) ABSTRACT

A semiconductor device includes a substrate, a gate structure over the substrate, a first sidewall spacer on a sidewall of the gate structure, a first diffusion region in the substrate and adjacent to the gate structure, the first sidewall spacer and the first diffusion region being on one side of the gate structure, and a first conductive layer in the first diffusion region, the first conductive layer being spaced apart from the first sidewall spacer.

### FIELD OF THE INVENTION

This invention relates in general to a semiconductor device and, more particularly, to an MOS transistor having an improved channel strain.

### BACKGROUND OF THE INVENTION

In the semiconductor industry, there is a continuing demand for smaller devices with higher speed and better performance. Various techniques have been proposed to improve the performance of semiconductor devices. FIG. 1 shows an MOSFET 100 that utilizes several such techniques.

As shown in FIG. 1, MOSFET 100 is formed on a semiconductor substrate 10 and includes a source 102 and a drain 104 each comprising a diffusion region in substrate 10. Source 102 and drain 104 define a channel region 106 therebetween. A gate dielectric layer 108 is formed over channel region 106 and overlies a portion of source 102 and drain 104. A gate (not numbered) including a polysilicon layer 110 and a salicide (self-aligned silicide) layer 112 is formed on gate dielectric 108, wherein salicide layer 112 comprises a metal silicide for improving conductance of the gate. Similarly, MOSFET 100 also includes a salicide layer 114 in source 102 and a salicide layer 116 in drain 104 for improving contact conductance to source 102 and drain 104, respectively. On each sidewall of the gate of MOSFET 100, a composite spacer including a first spacer 118 and a second spacer 120 is formed. A contact etch-stop layer (CESL) 122 is formed over the gate, source 102, drain 104, and the composite spacers. An inter-layer dielectric (ILD) layer 124 is provided over CESL 122. Metal contacts 126 are formed in vias (not numbered) in ILD 124 and CESL 122 to provide contacts to the gate, source 102, and drain 104. CESL 122 serves as an etch stop layer during the etching of ILD 124 to create the vias.

FIGS. 2A-2H are cross-sectional views illustrating a manufacturing process of MOSFET 100.

In FIG. 2A, substrate 10 comprising silicon is provided. Two diffusion regions are created in substrate 10 to form source 102 and drain 104, which define channel region 106 therebetween. Gate dielectric 108 is formed over channel region 106. A layer of polysilicon 110a is formed on gate dielectric 108.

In FIG. 2B, a first dielectric layer 118a comprising silicon oxide is deposited over polysilicon layer 110a and substrate 10 and also on the sidewalls of polysilicon layer 110a.

In FIG. 2C, a second dielectric layer 120a comprising silicon nitride is deposited over first dielectric layer 118a.

In FIG. 2D, first and second dielectric layers 118a and 120a are etched to form spacers 118b and 120b.

In FIG. 2E, spacers 118b and 120b are thinned by respective etchings to form spacers 118 and 120. As a result of the thinning of spacers 118b and 120b, a portion of the sidewalls of polysilicon layer 110a is exposed. Also, the etching of spacer 118b creates an undercut beneath spacer 120, as shown in FIG. 2E.

In FIG. 2F, a salicide process is carried out to form salicide layers 112, 114, and 116. In particular, a layer of metal is first deposited, followed by an annealing to allow reaction between the metal and the exposed silicon in substrate 10 and the exposed polysilicon in polysilicon layer 110a. As shown in FIG. 2F, salicide layers 114 and 116 are also partly formed under spacers 118 and 120. Then, unreacted metal on sidewalls 118 and 120 is removed. As a result, the gate comprising salicide layer 112 and polysilicon layer 110 is formed, where polysilicon layer 110 includes the remaining portion of polysilicon layer 110a.

In FIG. 2G, CESL 122 comprising, e.g., high stress silicon nitride, is deposited over the entire surface of the resultant structure of FIG. 2F.

In FIG. 2H, ILD layer 124 is formed by depositing a layer of dielectric such as silicon dioxide and etching the same to create the vias.

Then, CESL 122 is etched using ILD 124 as a mask, and metal contacts 126 are formed in the vias to provide contacts to salicide layers 112, 114, and 116. Thus, MOSFET 100 as shown in FIG. 1 is formed.

As discussed above, salicide layers 112, 114, and 116 increase the contact conductance to gate 112, source 102, and drain 104, respectively. As a result, MOSFET 100 has a high operation speed.

Also, it is well known that CESL 122 comprising high stress silicon nitride formed over source 102 and drain 104 also applies a stress to channel region 106. The stress applied to channel region 106 generates a strain therein, which in turn improves carrier mobilities in channel region 106. For example, if MOSFET 100 is n-type, CESL 122 may be formed to have a tensile stress, which creates a tensile stress in channel region 106. Consequently, electron mobility in channel region 106 is increased. Conversely, if MOSFET 100 is p-type, CESL 122 may be formed to have a compressive stress, which creates a compressive stress in channel region 106. Consequently, hole mobility in channel region 106 is increased. Accordingly, the operation speed of MOSFET 100 is improved.

In order to maximize the strain effect in channel region 106 caused by CESL 122, it is desirable to form CESL 122 as close to channel region 106 as possible. Therefore, it is desirable to thin spacers 118b and 120b as much as possible, as illustrated in FIG. 2E. However, a native oxide layer accumulates on silicon substrate 10 and polysilicon layer 110a, and prevents the reaction between the metal and silicon substrate 10 and polysilicon layer 110a. It is therefore necessary to perform a surface cleaning process, generally through the use of hydrofluoric acid, to remove the native oxide before the salicide process. If a single layer spacer comprising silicon oxide instead of the composite spacers is used, the surface cleaning process would also remove a portion of the oxide spacer. Consequently, a portion of the sidewalls of the gate would be exposed, and metal silicide would be formed thereon, which may result in metal bridging between the gate and source 102 or drain 104. In this regard, the use of the composite spacers including an oxide (first spacer 118) and a nitride (second spacer 120) avoids unwanted metal silicide on sidewalls of the gate or metal bridging between the gate and source 102 or drain 104.

However, as a result of the thinning of spacers 118b and 120b illustrated in FIG. 2E, salicide layers 114 and 116 are brought closer to channel region 106. Such encroachment by salicide layers 114 and 116 deteriorates the performances of MOSFET 100.

Also, in a semiconductor device including MOSFETs similar to MOSFET 100 of FIG. 1, CESL 122 of adjacent MOSFETs may merge with each other when a density of elements in the semiconductor device is high.

### SUMMARY OF THE INVENTION

A semiconductor device consistent with embodiments of the present invention includes a substrate, a gate structure over the substrate, a first sidewall spacer on a sidewall of the gate structure, a first diffusion region in the substrate and adjacent to the gate structure, the first sidewall spacer and the first diffusion region being on one side of the gate structure, and a first conductive layer in the first diffusion region, the first conductive layer being substantially spaced apart from the first sidewall spacer.

Consistent with embodiments of the present invention, there is also provided a semiconductor device that includes a substrate, a gate structure over the substrate, a first diffusion region in the substrate and adjacent to the gate structure, a first conductive layer in the first diffusion region, the first conductive layer being spaced apart from the gate structure, and a capping layer over the gate structure, a sidewall of the gate structure, and the substrate, wherein a portion of the capping layer is on a surface portion of the substrate between the first conductive layer and the gate structure.

Consistent with embodiments of the present invention, there is further provided a semiconductor device that includes a semiconductor substrate, a first MOS transistor formed on the semiconductor substrate, and a second MOS transistor formed on the semiconductor substrate. The first MOS transistor includes a gate structure over the semiconductor substrate, a sidewall spacer on a sidewall of the gate structure, a diffusion region in the semiconductor substrate and adjacent to the gate structure, the sidewall spacer and the diffusion region being on one side of the gate structure, and a conductive layer in the diffusion region, the conductive layer being spaced apart from the sidewall spacer.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings,

FIG. 1 shows a conventional MOSFET;

FIGS. 2A-2H illustrate a manufacturing process of the MOSFET of FIG. 1;

FIG. 3 shows an MOSFET consistent with a first embodiment of the present invention;

FIG. 4 shows an MOSFET consistent with a second embodiment of the present invention;

FIG. 5 shows an MOSFET consistent with a third embodiment of the present invention;

FIG. 6A shows an MOSFET consistent with one aspect of the present invention;

FIG. 6B shows an MOSFET consistent with another aspect of the present invention;

FIGS. 7A-7H illustrate a manufacturing process of the MOSFET of FIG. 3; and

FIGS. 8A-8C CMOS devices consistent with embodiments of the present invention.

### DESCRIPTION OF THE EMBODIMENTS

Reference will now be made in detail to the present embodiments of the invention, examples of which are illustrated in the accompanying drawings. Wherever possible, the same reference numbers will be used throughout the drawings to refer to the same or like parts.

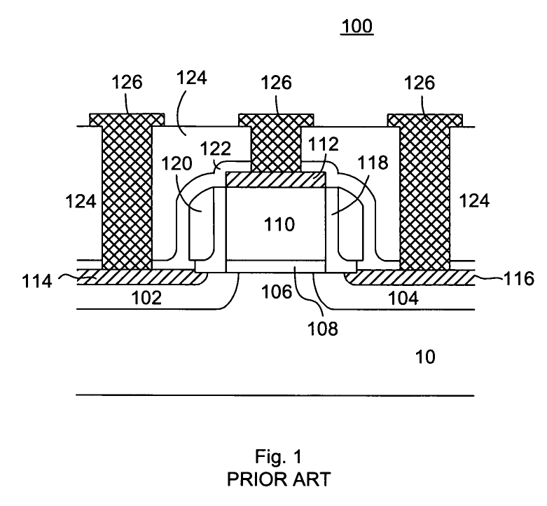

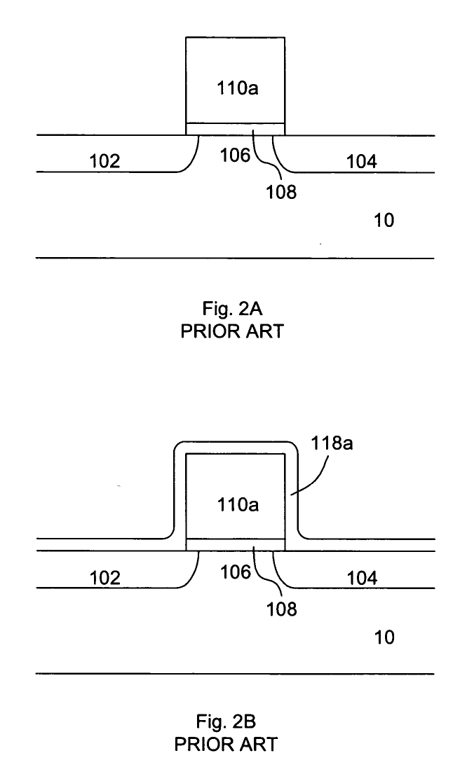

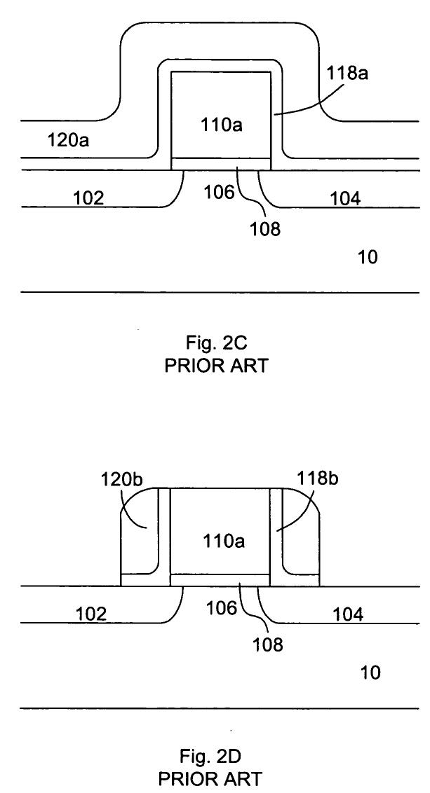

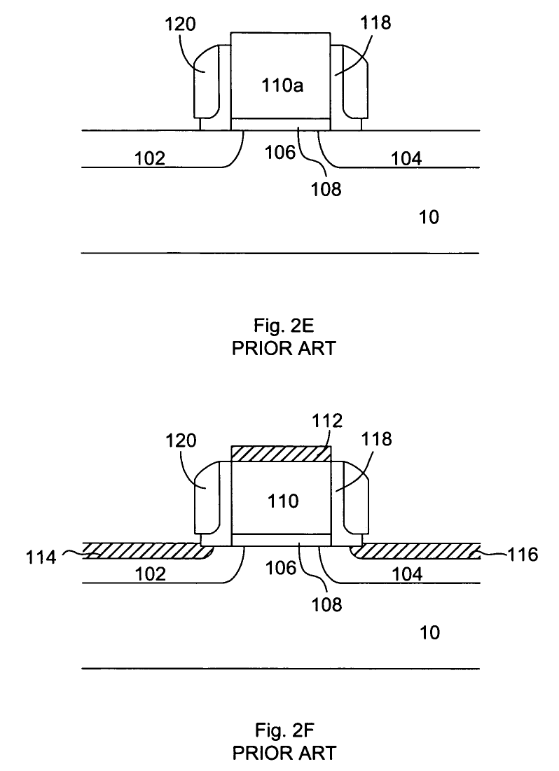

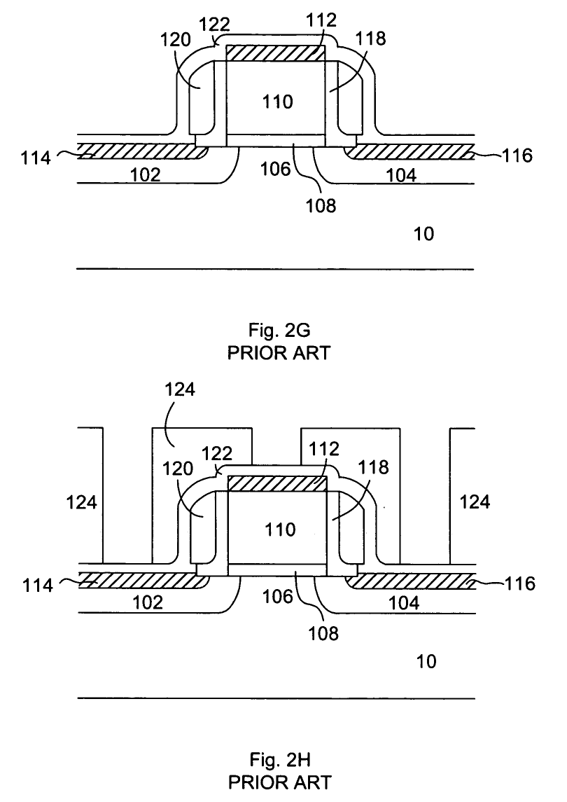

Consistent with the present invention, there are provided embodiments of a novel MOSFET including conductive layers in source and drain regions of the MOSFET and spacers on sidewalls of a gate of the MOSFET, wherein the conductive layers are spaced apart from the spacers, and therefore are spaced further apart from a channel region of the MOSFET than in conventional MOSFETs such as MOSFET 100 shown in FIG. 1. As a result, encroachment by the conductive layers in the source and drain regions is reduced or avoided.

Consistent with the present invention, there are also provided embodiments of a novel MOSFET that includes a contact etch stop layer (CESL) that is closer to a channel region of the MOSFET, and therefore has an improved channel strain, as compared to conventional MOSFETs such as MOSFET 100 shown in FIG. 1.

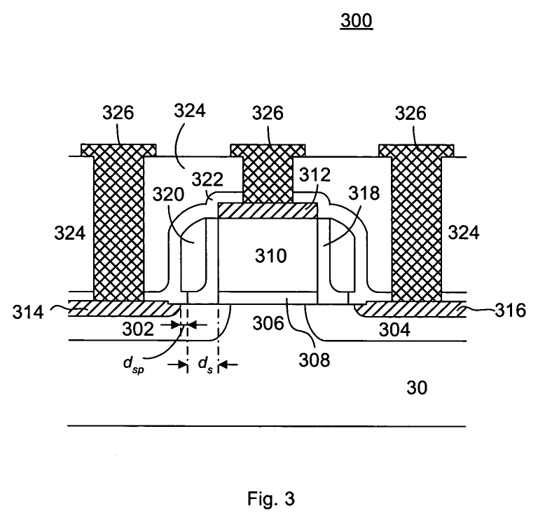

FIGS. 3-5 show MOSFETs consistent with embodiments of the present invention.

In FIG. 3, an MOSFET 300 consistent with a first embodiment of the present invention is formed on a semiconductor substrate 30. Semiconductor substrate 30 may comprise a silicon substrate. MOSFET 300 includes a source 302 and a drain 304 each comprising a diffusion region in substrate 30. Source 302 and drain 304 define a channel region 306 therebetween. In one aspect, channel region 306 has a length of about 0.01 μm to 10 μm. A gate dielectric layer 308 is formed over channel region 306 and overlies a portion of source 302 and drain 304. Gate dielectric layer 308 may comprise silicon oxide or a high-k dielectric. A gate (not numbered) including a first layer 310 and a salicide layer 312 is formed on gate dielectric 308. First layer 310 may comprise a metal or polysilicon, wherein the polysilicon may be n-type if MOSFET 300 is an n-type MOSFET and may be p-type if MOSFET 300 is a p-type MOSFET. MOSFET 300 also includes a conductive layer 314 in source 302 and a conductive layer 316 in drain 304. Salicide layer 312 and conductive layers 314 and 316 may each comprise a metal silicide, wherein the metal may be titanium, cobalt, nickel, or platinum. Salicide layer 312 and conductive layers 314 and 316 may have a thickness of approximately 5 nm to 100 nm. Alternatively, conductive layers 314 and 316 may comprise silicon germanium formed by an epitaxial growth or a physical vapor deposition (PVD) process. On each sidewall of the gate of MOSFET 300, a composite spacer including a first spacer 318 and a second spacer 320 is formed. A contact etch-stop layer (CESL) or a capping layer 322 comprising a high stress material, such as high stress silicon nitride, silicon carbide, or silicon germanium, is formed over the gate, source 302, drain 304, and the composite spacers. In one aspect, the stress of the high-stress material ranges from −5 GPa (10⁹ pascal) to 5 GPa. In another aspect, MOSFET 300 is n-type, the gate of MOSFET 300 comprises a gate electrode suitable for an n-type MOSFET, and the stress in CESL 322 is tensile. As a result, channel region 306 has a tensile stress, which increases electron mobility therein. In another aspect, MOSFET 300 is p-type, the gate of MOSFET 300 comprises a gate electrode suitable for a p-type MOSFET, and the stress in CESL 322 is compressive. As a result, channel region 306 has a compressive stress, which increases hole mobility therein. In an aspect, CESL 322 has a thickness of about 10 nm to 100 nm. An ILD layer 324 is provided over CESL 322. Metal contacts 326 are formed in vias (not numbered) in ILD 324 and CESL 322 to provide contacts to the gate, source 302, and drain 304. CESL 322 also serves as an etch stop layer during the etching of ILD 324 to create the vias.

As shown in FIG. 3 and consistent with the first embodiment of the present invention, conductive layers 314 and 316 are spaced apart from spacers 318 and 320, and therefore are respectively spaced further away from channel region 306, as compared to those in MOSFET 100 of FIG. 1. As a result, the possibility of encroachment by conductive layers 314 and 316 in MOSFET 300 is substantially reduced or entirely avoided.

In one aspect, a distance dₛₚ between conductive layers 314/316 and spacers 318 is about 10%˜120% of a width dₛ of spacer 318. In another aspect, the distance dₛₚ between conductive layers 314/316 and spacers 318 is substantially more than 75% of the width dₛ of spacers 318. In one aspect, the distance dₛₚ between conductive layers 314/316 and spacers 318 is approximately 0.5 nm to 0.05 μm. In another aspect, the distance dₛₚ between conductive layers 314/316 and spacers 318 is approximately 0.03 μm to 0.04 μm.

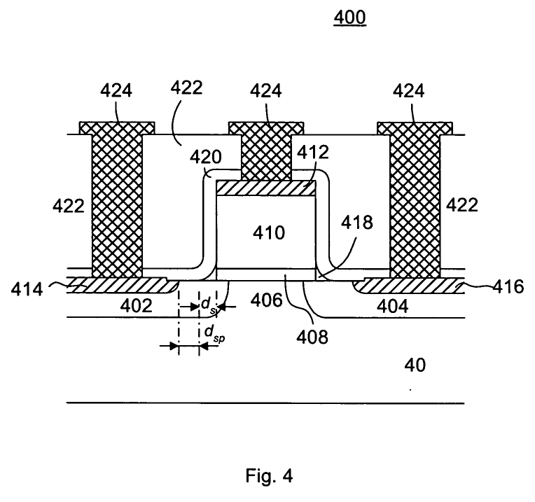

FIG. 4 shows an MOSFET 400 consistent with a second embodiment of the present invention. MOSFET 400 is formed on a semiconductor substrate 40. Semiconductor substrate 40 may comprise a silicon substrate. MOSFET 400 includes a source 402 and a drain 404 each comprising a diffusion region in substrate 40. Source 402 and drain 404 define a channel region 406 therebetween. In one aspect, channel region 406 has a length of about 0.01 μm to 10 μm. A gate dielectric layer 408 is formed over channel region 406 and overlies a portion of source 402 and drain 404. Gate dielectric layer 408 may comprise silicon oxide or a high-k dielectric. A gate (not numbered) including a first layer 410 and a salicide layer 412 is formed on gate dielectric 408. First layer 410 may comprise a metal or polysilicon, wherein the polysilicon may be n-type if MOSFET 400 is an n-type MOSFET and may be p-type if MOSFET 400 is a p-type MOSFET. MOSFET 400 also includes a conductive layer 414 in source 402 and a conductive layer 416 in drain 404. Salicide layer 412 and conductive layers 414 and 416 may each comprise a metal silicide, wherein the metal may be titanium, cobalt, nickel, or platinum. Alternatively, conductive layers 414 and 416 may comprise silicon germanium formed by an epitaxial growth or a PVD process. Salicide layer 412 and conductive layers 414 and 416 may have a thickness of approximately 5 nm to 100 nm. On each sidewall of the gate of MOSFET 400 there is a residual spacer 418. Residual spacers 418 are the result of the thinning of a composite spacer, as will be discussed below. A contact etch-stop layer (CESL) or a capping layer 420 comprising a high stress material such as high stress silicon nitride is formed over the gate, source 402, drain 404, and spacers 418. In one aspect, MOSFET 400 is n-type, the gate of MOSFET 400 comprises a gate electrode suitable for an n-type MOSFET, and the stress in CESL 420 is tensile. In another aspect, MOSFET 400 is p-type, the gate of MOSFET 400 comprises a gate electrode suitable for a p-type MOSFET, and the stress in CESL 420 is compressive. In one aspect, CESL 420 has a thickness of about 10 nm to 100 nm. An ILD layer 422 is provided over CESL 420, and metal contacts 424 are formed in vias (not numbered) in ILD 422 and CESL 420 to provide contacts to the gate, source 402, and drain 404.

In one aspect, a distance dₛₚ between conductive layers 414/416 and spacers 418 is about 20%˜200% of a width dₛ of spacers 418. In another aspect, the distance dₛₚ between conductive layers 414/416 and spacers 418 is about 1 nm to 0.1 μm.

As shown in FIG. 4 and consistent with the second embodiment of the present invention, in MOSFET 400, CESL 420 comprising a high stress material is separated from gate dielectric 408 by only a residual spacer 418, and is therefore closer to channel region 406, as compared to those in MOSFET 300 of FIG. 3 or MOSFET 100 of FIG. 1. Accordingly, a higher channel strain is achieved in MOSFET 400.

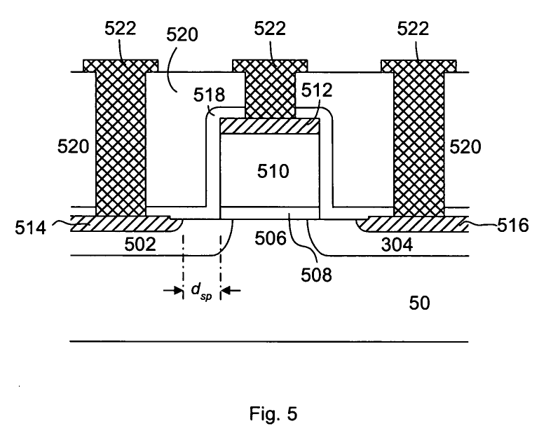

FIG. 5 shows an MOSFET 500 consistent with a third embodiment of the present invention. MOSFET 500 is formed on a semiconductor substrate 50. Semiconductor substrate 50 may comprise a silicon substrate. MOSFET 500 includes a source 502 and a drain 504 each comprising a diffusion region in substrate 50. Source 502 and drain 504 define a channel region 506 therebetween. In one aspect, channel region 506 has a length of about 0.01 μm to 10 μm. A gate dielectric layer 508 is formed over channel region 506 and overlies a portion of source 502 and drain 504. Gate dielectric layer 508 may comprise silicon oxide or a high-k dielectric. A gate (not numbered) including a first layer 510 and a salicide layer 512 is formed on gate dielectric 508. First layer 510 may comprise a metal or polysilicon, wherein the polysilicon may be n-type if MOSFET 500 is an n-type MOSFET and may be p-type if MOSFET 500 is a p-type MOSFET. MOSFET 500 also includes a conductive layer 514 in source 502 and a conductive layer 516 in drain 504. Salicide layer 512 and conductive layers 514 and 516 may each comprise a metal silicide, wherein the metal may be titanium, cobalt, nickel, or platinum. Alternatively, conductive layers 514 and 516 may comprise silicon germanium formed by an epitaxial growth or a PVD process. Salicide layer 512 and conductive layers 514 and 516 may have a thickness of approximately 5 nm to 100 nm. A contact etch-stop layer (CESL) or a capping layer 518 comprising a high stress material such as high stress silicon nitride is formed over the gate, sidewalls of gate dielectric 508, source 502, and drain 504. In one aspect, MOSFET 500 is n-type, the gate of MOSFET 500 comprises a gate electrode suitable for an n-type MOSFET, and the stress in CESL 518 is tensile. In another aspect, MOSFET 500 is p-type, the gate of MOSFET 500 comprises a gate electrode suitable for a p-type MOSFET, and the stress in CESL 518 is compressive. In an aspect, CESL 518 has a thickness of about 10 nm to 100 nm. An ILD layer 520 is provided over CESL 518, and metal contacts 522 are formed in vias (not numbered) in ILD 520 and CESL 518 to provide contacts to the gate, source 502, and drain 504.

In one aspect, a distance dₛₚ between conductive layers 514/516 and channel region 506 is approximately 10 nm to 0.15 μm.

Because CESL 518 is formed directly on the sidewalls of gate dielectric 508, the distance between CESL 518 and channel region 506 reaches a minimum value. Therefore, the channel strain effect in MOSFET 500 is maximized.

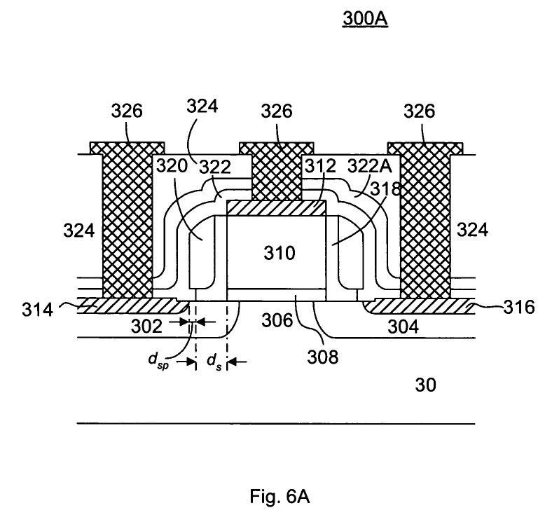

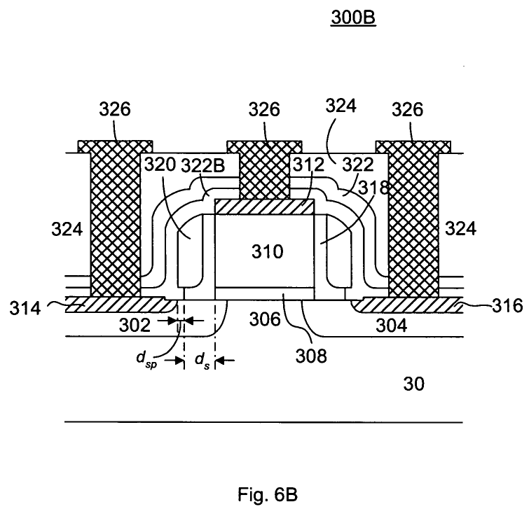

In one aspect, MOSFETs consistent with embodiments of the present invention may further include a composite CESL comprising multiple layers of high stress materials to provide a better strain to the channel region. For example, FIG. 6A shows an MOSFET 300A that includes a composite CESL but is otherwise the same as the structure of MOSFET 300 of FIG. 3. More particularly, MOSFET 300A includes a composite CESL that includes two layers of high stress materials 322 and 322A. Layers 322 and 322A may comprise different materials or the same material With different stresses. Similarly, the composite CESL comprising high stress materials may replace CESL 420 in MOSFET 400 or CESL 518 in MOSFET 500

In another aspect, MOSFETs consistent with embodiments of the present invention may further include an adhesion layer between the substrate and the CESL to improve device reliability. For example, FIG. 6B shows an MOSFET 300B that includes an adhesion layer but is otherwise the same as the structure of MOSFET 300 of FIG. 3. More particularly, MOSFET 300B includes an adhesion layer 322B between CESL 322 and substrate 30. Adhesion layer 322B may contain silicon nitride, silicon oxide, oxynitride, or silicon carbide. Similarly, an adhesion layer may be included in MOSFET 400 or MOSFET 500.

As shown in FIGS. 3-5 and 6A-6B, MOSFETs consistent with embodiments of the present invention have conductive layers formed in the source/drain regions and spaced substantially apart from the channel regions thereof. Therefore, encroachment by the conductive layers is reduced or avoided.

In addition, as compared to conventional MOSFETs such as MOSFET 100 of FIG. 1, MOSFETs as illustrated in FIGS. 4 and 5 include a CESL that is closer to the channel region, which results in a better channel strain effect and a better performance. Also because the CESL is closer to the channel region of the MOSFET, when MOSFETs consistent with embodiments of the present invention are formed with a high density in a semiconductor circuit, the probability of CESLs of two adjacent MOSFETs merging with each other is lower than for conventional MOSFETs.

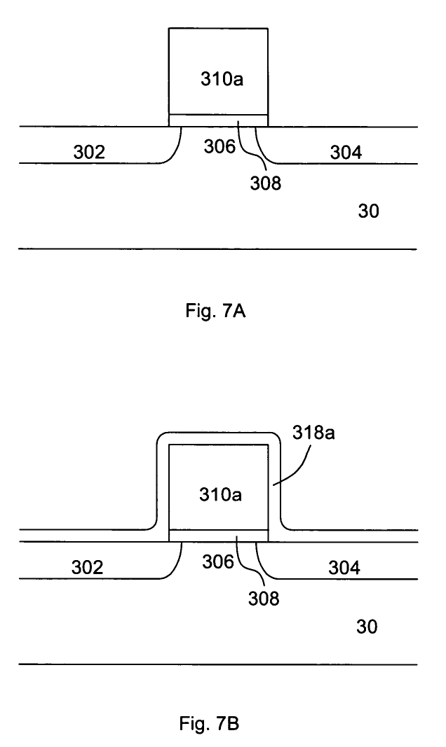

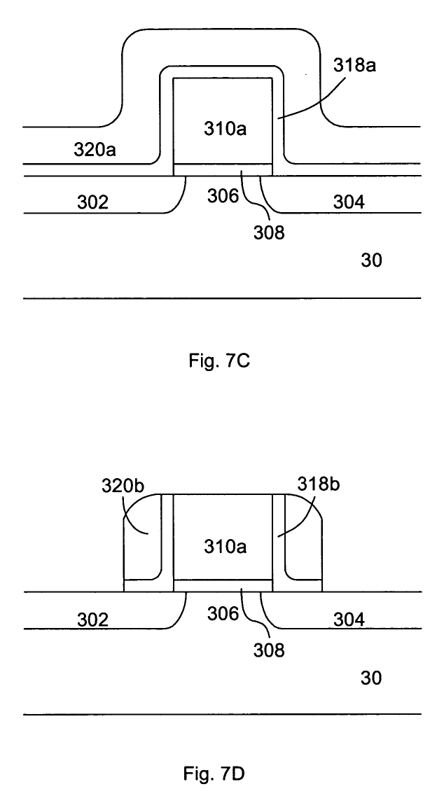

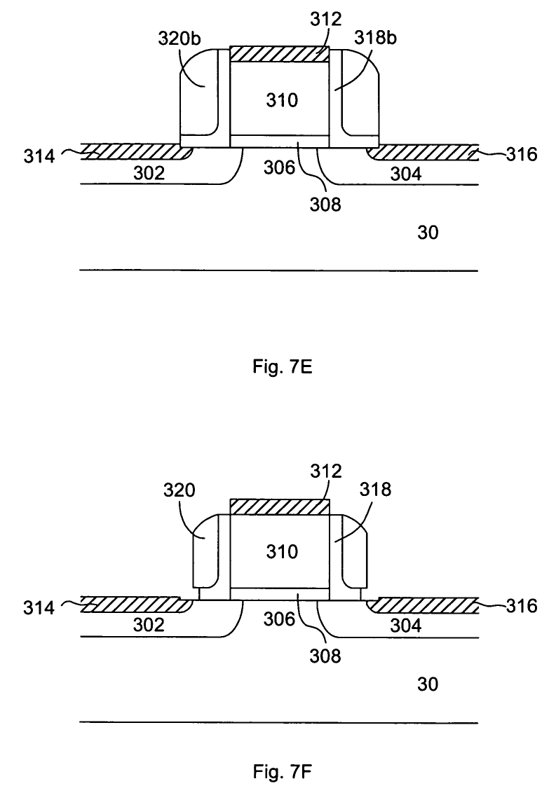

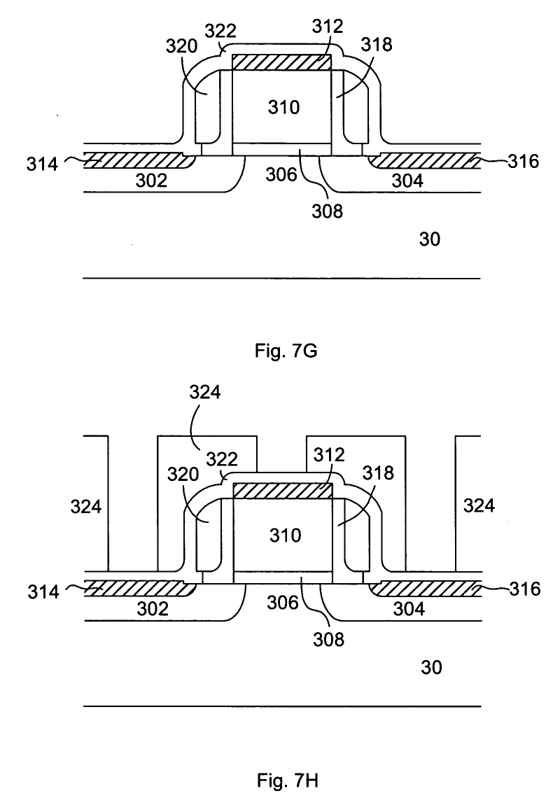

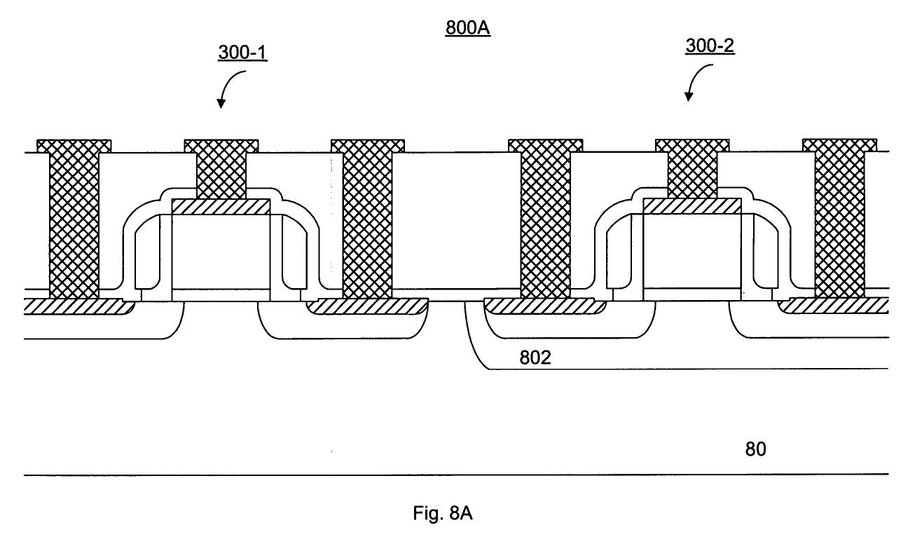

Consistent with embodiments of the present invention, there is also provided a method for manufacturing the MOSFETs shown in FIGS. 3-5 and 6A-6B. FIGS. 7A-7H illustrate a manufacturing process of MOSFET 300 of FIG. 3.

In FIG. 7A, substrate 30 comprising silicon is provided. Two diffusion regions are created through implantation and diffusion in substrate 30 to form source 302 and drain 304, which define channel region 306 therebetween. Gate dielectric 308 is formed over channel region 306. A layer of polysilicon 310a is formed on gate dielectric 308.

In FIG. 7B, a first dielectric layer 318a comprising silicon oxide is deposited over polysilicon layer 310a and substrate 30 and also on the sidewalls of polysilicon layer 310a.

In FIG. 7C, a second dielectric layer 320a comprising silicon nitride is deposited over first dielectric layer 318a.

In FIG. 7D, first and second dielectric layers 318a and 320a are etched to form spacers 318b and 320b.

In FIG. 7E, a salicide process is carried out to form salicide layer 312. Conductive layers 314 and 316 may be simultaneously formed as layers of metal silicide. In particular, a layer of metal is first deposited, followed by an annealing to allow reaction between the metal and the exposed silicon in substrate 30 and the exposed polysilicon in polysilicon layer 310a. As shown in FIG. 7E, conductive layers 314 and 316 are also partly formed under spacers 318b and 320b. Then, unreacted metal on sidewalls 318b and 320b is removed. As a result, the gate comprising salicide layer 312 and polysilicon layer 310 is formed, where polysilicon layer 310 includes the remaining portion of polysilicon layer 310a. Alternatively, conductive layers 314 and 316 may be separately formed as silicon germanium through a PVD process or epitaxial growth.

In FIG. 7F, spacers 318b and 320b are thinned by respective etchings to form spacers 318 and 320. As shown in FIG. 7F, the etching of spacer 318b also creates an undercut beneath spacer 320. In other words, spacer 320 overlies spacer 318 and spacer 318 extends beneath only a portion of spacer 320. The etching of spacers 318b and 320b may be carried out by anisotropic etch or isotropic etch. As a result of the thinning of spacers 318b and 320b, spacers 318 and 320 are spaced apart from conductive layers 314 and 316, as shown in FIG. 7F.

In FIG. 7G, CESL 322 comprising, e.g., high stress silicon nitride, is deposited over the entire surface of the resultant structure of FIG. 7F through a chemical vapor deposition (CVD) process or an atomic layer deposition (ALD) process. Particularly, if MOSFET 300 is n-type, CESL 322 is formed to have a tensile stress by, e.g., a heat treatment. If MOSFET 300 is p-type, a high Young's modulus material may be used as CESL 322 to provide a compressive stress. CESL 322 may then be treated either thermally, or by implantation, or with plasma, or through UV radiation. As shown in FIG. 7G, because spacers 318 and 320 are spaced apart from conductive layers 314 and 316, CESL 322 is also partly formed between conductive layers 314 and 316 and spacers 318 and 320 and on a surface portion of semiconductor substrate 30 between conductive layers 314 and 316 and the gate of MOSFET 300.

In FIG. 7H, ILD layer 324 is formed by depositing a layer of dielectric such as silicon dioxide and etching the same to create the vias.

Then, CESL 322 is etched using ILD 324 as a mask, and metal contacts 326 are formed in the vias to provide contacts to salicide layer 312 and conductive layers 314 and 316. Thus, MOSFET 300 as shown in FIG. 3 is formed.

The manufacturing processes for forming MOSFET 400 of FIG. 4 and MOSFET 500 of FIG. 5 are similar to the above process for forming MOSFET 300 of FIG. 3, except that in the thinning step shown in FIG. 7F, spacers 318b and 320b are further etched. Particularly, spacer 320b is completely removed to result in residual spacers 418 in MOSFET 400, and both spacers 318b and 320b are completely removed to result in the structure shown in FIG. 5. To manufacture MOSFET 300A of FIG. 6A, an additional step for forming high stress layer 322A is performed before the deposition of ILD 324. To manufacture MOSFET 300B of FIG. 6B, an additional step for forming adhesion layer 322B is performed before the formation of CESL 322. The manufacturing processes for MOSFETs 400, 500, 300A, and 300B should now be understood by one skilled in the art and are not further discussed in detail herein.

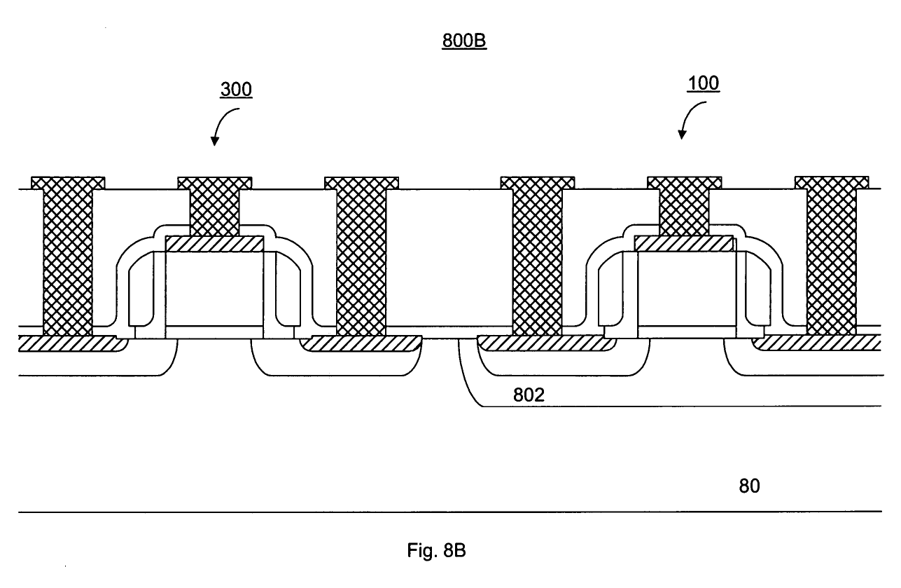

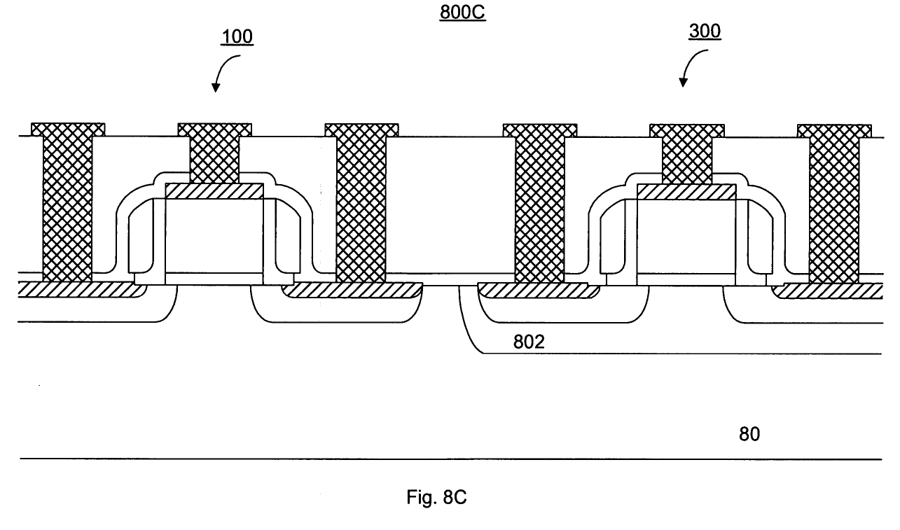

MOSFETs consistent with embodiments of the present invention may be manufactured as either n-type or p-type and both an n-type MOSFET and a p-type MOSFET consistent with embodiments of the present invention may be formed together on a semiconductor substrate to form a CMOS device. For example, FIG. 8A shows a CMOS device 800A including two MOSFETs 300 (300-1, 300-2) formed on a semiconductor substrate 80, wherein MOSFET 300-1 is formed on semiconductor substrate 80, and MOSFET 300-2 is formed in a diffusion well 802 in substrate 80. MOSFETs 300-1 and 300-2 may respectively be a p-type MOSFET and an n-type MOSFET, wherein substrate 80 is n-type and diffusion well 802 is p-type. Alternatively, MOSFETs 300-1 and 300-2 may respectively be an n-type MOSFET and a p-type MOSFET, wherein substrate 80 is p-type and diffusion well 802 is n-type. FIG. 8B shows a CMOS device 800B including one MOSFET 300 formed on a semiconductor substrate 80 and one MOSFET 100 formed in a diffusion well 802 in substrate 80. MOSFETs 300 and 100 in CMOS 800B may respectively be a p-type MOSFET and an n-type MOSFET, wherein substrate 80 is n-type and diffusion well 802 is p-type. Alternatively, MOSFETs 300 and 100 in CMOS 800B may respectively be an n-type MOSFET and a p-type MOSFET, wherein substrate 80 is p-type and diffusion well 802 is n-type. In accordance with a further alternative construction shown in FIG. 8C, MOSFET 100 may be formed on substrate 80, while MOSFET 300 is formed in diffusion well 802.

One skilled in the art should now appreciation the formation of CMOS devices including the MOSFETs shown in FIGS. 4-5 and 6A-6B and consistent with embodiments of the present invention.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device, comprising:
a substrate;
a gate structure over the substrate;
a first sidewall spacer on a sidewall of the gate structure;
a first diffusion region in the substrate and adjacent to the gate structure, the first sidewall spacer and the first diffusion region being on one side of the gate structure; and
a first conductive layer in the first diffusion region, the first conductive layer being substantially spaced apart from the first sidewall spacer.

2. The device of claim 1, wherein a distance between the first conductive layer and the first sidewall spacer is approximately 20%˜200% of a width of the first sidewall spacer.

3. The device of claim 1, wherein a distance between the first conductive layer and the first sidewall spacer is approximately 1 nm to 0.1 μm.

4. The device of claim 1, wherein the first sidewall spacer comprises a first spacer and a second spacer, the first spacer comprising an oxide and the second spacer comprising a nitride.

5. The device of claim 4, wherein the second spacer is above the first spacer and the first spacer extends beneath only a portion of the second spacer.

6. The device of claim 4, wherein a distance between the first conductive layer and the first sidewall spacer is approximately 10%˜120% of a width of the first sidewall spacer.

7. The device of claim 4, wherein a distance between the first conductive layer and the first sidewall spacer is approximately 0.5 nm to 0.05 μm.

8. The device of claim 1, wherein the first conductive layer comprises a metal silicide or silicon germanium, wherein a metal of the metal silicide comprises titanium, cobalt, nickel, or platinum.

9. The device of claim 1, further comprising a second sidewall spacer on another sidewall of the gate structure.

10. A semiconductor device, comprising:
a substrate;
a gate structure over the substrate;
a first diffusion region in the substrate and adjacent to the gate structure;
a first conductive layer in the first diffusion region, the first conductive layer being spaced apart from the gate structure; and
a capping layer over the gate structure, a sidewall of the gate structure, and the substrate, wherein a portion of the capping layer is on a surface portion of the substrate between the first conductive layer and the gate structure.

11. The device of claim 10, wherein the gate structure comprises a layer of polysilicon and a layer of metal silicide, wherein a metal of the metal silicide comprises titanium, cobalt, nickel, or platinum.

12. The device of claim 10, wherein a distance between the first conductive layer and the gate structure is approximately 10 nm to 0.15 μm.

13. The device of claim 10, wherein the first conductive layer comprises a metal silicide or silicon germanium, wherein a metal of the metal silicide comprises titanium, cobalt, nickel, or platinum.

14. The device of claim 10, wherein the capping layer comprises a nitride.

15. The device of claim 10, wherein the capping layer has a thickness of approximately 10 nm˜100 nm.

16. The device of claim 10, further comprising a second diffusion region in the substrate and adjacent to the gate structure, the second diffusion region and the first diffusion region being on opposite sides of the gate structure, wherein the second diffusion region includes a second conductive layer spaced apart from the gate structure.

17. The device of claim 16, wherein the first diffusion region and the second diffusion region define a channel region therebetween, and a length of the channel region is approximately 0.01 μm to 10 μm.

18. The device of claim 10, further comprising a sidewall spacer on a portion of a sidewall of the gate structure.

19. A semiconductor device, comprising:
a semiconductor substrate;
a first MOS transistor formed on the semiconductor substrate, including
a gate structure over the semiconductor substrate,
a sidewall spacer on a sidewall of the gate structure,
a diffusion region in the semiconductor substrate and adjacent to the gate structure, the sidewall spacer and the diffusion region being on one side of the gate structure, and
a conductive layer in the diffusion region, the conductive layer being spaced apart from the sidewall spacer; and
a second MOS transistor formed on the semiconductor substrate.

20. The device of claim 19, wherein a distance between the first conductive layer and the gate structure is approximately 10 nm to 0.15 μm.
